(19) United States
(12) Patent Application Publication
(10) Pub. No.: US 2014/0054598 A1
(43) Pub. Date: Feb. 27, 2014

(54) SEMICONDUCTOR DEVICE AND METHOD FOR MANUFACTURING SEMICONDUCTOR DEVICE

(71) Applicant: Kabushiki Kaisha Toshiba, Minato-ku (JP)

(72) Inventor: Jeoungchill SHIM, Kanagawa (JP)

(21) Appl. No.: 13/921,424

(22) Filed: Jun. 19, 2013

(30) Foreign Application Priority Data
Aug. 27, 2012 (JP) 2012-186458

(51) Int. Cl. H01L 29/20; H01L 29/66

(52) U.S. Cl. CPC H01L 29/2003; H01L 29/66431
USPC 257/76; 438/285

(57) ABSTRACT

Certain embodiments provide semiconductor device including a semiconductor layer including a channel layer, a barrier layer, and a cap layer, the semiconductor layer provided on a semiconductor substrate, a drain electrode and a source electrode, an opening of the cap layer, and a gate electrode. The drain electrode and the source electrode are provided on the barrier layer. The opening is provided in the cap layer provided between the drain electrode and the source electrode, the opening being separated from the drain electrode and the source electrode. The gate electrode is provided so as to be in contact with the barrier layer exposed in the opening of the cap layer and also insulated from a side surface of the opening of the cap layer. Inside the opening, a distance between the gate electrode and the side surface of the opening increases with a decreasing distance from the barrier layer.

### CROSS REFERENCE TO RELATED APPLICATIONS

This application is based upon and claims the benefit of priority from the prior Japanese Patent Application No. 2012-186458 filed in Japan on Aug. 27, 2012; the entire contents of which are incorporated herein by reference.

### FIELD

Embodiments described herein relate generally to semiconductor device and method for manufacturing semiconductor device.

### BACKGROUND

For example, HEMT (High Electron Mobility Transistor) in which a barrier layer made of AlGaN is provided on a channel layer made of GaN or the like is generally known as a semiconductor device using a nitride semiconductor having a GaN/AlGaN heterostructure. If such a semiconductor device is operated by applying a voltage to a gate electrode, a phenomenon in which a drain current drastically decreases occurs. The phenomenon is referred to as a current collapse. To inhibit the current collapse, a cap layer made of GaN or AlGaN is normally provided on the barrier layer. The gate electrode is provided so as to be in contact with the side face of an opening provided in the cap layer like filling the opening.

The current collapse is caused by a trap level formed on a surface of a nitride semiconductor. To inhibit the current collapse, it is necessary to provide the cap layer thickly.

However, the gate electrode is in contact with the cap layer and thus, a leak current flows to the cap layer. That is, if the cap layer is made thicker to inhibit the current collapse, a problem of an increased leak current arises.

Problems of an occurrence of the current collapse and an occurrence of the leak current caused by the cap layer being provided arise particularly conspicuously in a GaN semiconductor device described above, but also arise similarly in an Si semiconductor device and a GaAs semiconductor device.

### BRIEF DESCRIPTION OF THE DRAWINGS

FIG. 1 is a sectional view showing a semiconductor device according to a first embodiment;

FIG. 2 is a sectional view illustrating a method for manufacturing the semiconductor device according to the first embodiment;

FIG. 3 is a sectional view illustrating the method for manufacturing the semiconductor device according to the first embodiment;

FIG. 4 is a sectional view illustrating the method for manufacturing the semiconductor device according to the first embodiment;

FIG. 5 is a sectional view illustrating the method for manufacturing the semiconductor device according to the first embodiment;

FIG. 6 is a sectional view illustrating the method for manufacturing the semiconductor device according to the first embodiment;

FIG. 7 is a sectional view illustrating the method for manufacturing the semiconductor device according to the first embodiment;

FIG. 8 is a sectional view showing a semiconductor device according to a second embodiment;

FIG. 9 is a sectional view showing a semiconductor device according to a third embodiment;

FIG. 10 is a sectional view illustrating the method for manufacturing the semiconductor device according to the third embodiment;

FIG. 11 is a sectional view illustrating the method for manufacturing the semiconductor device according to the third embodiment;

FIG. 12 is a sectional view illustrating the method for manufacturing the semiconductor device according to the third embodiment;

FIG. 13 is a sectional view illustrating the method for manufacturing the semiconductor device according to the third embodiment;

FIG. 14 is a sectional view illustrating the method for manufacturing the semiconductor device according to the third embodiment;

FIG. 15 is a sectional view illustrating the method for manufacturing the semiconductor device according to the third embodiment; and

FIG. 16 is a sectional view showing a semiconductor device according to a fourth embodiment;

### DETAILED DESCRIPTION

Certain embodiments provide semiconductor device including a semiconductor layer including a channel layer, a barrier layer, and a cap layer, the semiconductor layer provided on a semiconductor substrate, a drain electrode and a source electrode, an opening of the cap layer, and a gate electrode. The drain electrode and the source electrode are provided on the barrier layer. The opening is provided in the cap layer provided between the drain electrode and the source electrode, the opening being separated from the drain electrode and the source electrode. The gate electrode is provided so as to be in contact with the barrier layer exposed in the opening of the cap layer and also insulated from a side surface of the opening of the cap layer. Inside the opening, a distance between the gate electrode and the side surface of the opening increases with a decreasing distance from the barrier layer.

Certain embodiments provide method for manufacturing semiconductor device including forming a channel layer, a barrier layer, and a cap layer on a semiconductor substrate, forming a drain electrode and a source electrode, forming an opening in the cap layer, forming a first dielectric film, forming a sidewall inside the opening, and forming a gate electrode. The drain electrode and the source electrode are formed on the barrier layer. The opening is formed in the cap layer provided between the drain electrode and the source electrode, the opening being separated from the drain electrode and the source electrode. The first dielectric film is formed on the cap layer including the opening. The sidewall is formed by performing anisotropic etching on the first dielectric film. The gate electrode is formed so that at least the opening in which the sidewall is provided is filled.

Certain embodiments provide method for manufacturing semiconductor device including forming a channel layer, a barrier layer, a cap layer, and a second dielectric film on a semiconductor substrate, forming a drain electrode and a source electrode, forming an opening in the cap layer and the second dielectric film, forming a first dielectric film, forming a sidewall inside the opening, and forming a gate electrode. The drain electrode and the source electrode are formed on the barrier layer. The opening is formed in the cap layer and the second dielectric film provided between the drain electrode and the source electrode, the opening being separated from the drain electrode and the source electrode. The first dielectric film is formed on the second dielectric film including the opening. The sidewall is formed by performing anisotropic etching on the first dielectric film. The gate electrode is formed so that at least the opening in which the sidewall is provided is filled.

Semiconductor devices and methods for manufacturing a semiconductor device according to the embodiments will be described below.

### First Embodiment

FIG. 1 is a sectional view showing a semiconductor device according to a first embodiment. In a semiconductor device 10 shown in FIG. 1, a buffer layer 12 made of GaN, a channel layer 13 made of GaN, and a barrier layer 14 made of AlGaN are stacked in this order on a surface of a semi-insulating semiconductor substrate 11 made of, for example, SiC. A two dimensional electron gas layer 15 arises on the barrier layer side of the channel layer 13. When a semiconductor layer is mentioned below, the semiconductor layer includes the channel layer 13, the barrier layer 14, and a cap layer 18 described below. Particularly when a nitride semiconductor layer is mentioned, the nitride semiconductor layer includes the channel layer 13 made of GaN, the barrier layer 14 made of AlGaN, and the cap layer 18 made of GaN.

In addition to SiC, a substrate made of, for example, Si, sapphire, GaN, AlN or the like may be used as the semi-insulating semiconductor substrate 11. When the semi-insulating semiconductor substrate made of GaN is applied, the buffer layer is not a necessarily required layer.

A drain electrode 16 and a source electrode 17 are provided in predetermined positions on the surface of the barrier layer 14 by being spaced therebetween. Each of these electrodes 16, 17 has, for example, a Ti layer, Nb layer, and Pt layer stacked in this order. Each of the drain electrode 16 and the source electrode 17 is provided so that the Ti layer is in ohmic contact with the surface of the barrier layer 14.

On the surface of the barrier layer 14, for example, the cap layer 18 made of GaN is provided between the drain electrode 16 and the source electrode 17. The cap layer 18 has an opening 18a in a position separated from the drain electrode 16 and the source electrode 17. A side surface of the opening 18a is substantially perpendicular to the surface of the semi-insulating semiconductor substrate 11.

A gate electrode 19 is provided on the surface of the barrier layer 14 exposed through the opening 18a of the cap layer 18. The gate electrode 19 has, for example, an Ni layer and Au layer stacked in this order. The gate electrode 19 is provided in such a way that the Ni layer is Schottky-joined to the surface of the barrier layer 14.

The gate electrode 19 includes a leg portion 19a having an increasing length with an increasing distance from the barrier layer 14 and an eaves portion 19b having substantially the same length as the upper end of the leg portion 19a. The gate electrode 19 has a T shape in which the eaves portion 19b is provided on the leg portion 19a. Incidentally, the length of the gate electrode 19 means the length in a direction parallel to the direction in which a drain-source current flows.

The gate electrode 19 is provided so that the whole leg portion 19a is arranged inside the opening 18a of the cap layer 18. Further, the gate electrode 19 is provided so that the side face of the leg portion 19a is separated from the side face of the opening 18a. That is, the gate electrode 19 is provided so as to be insulated from the cap layer 18. With the gate electrode 19 being provided as described above, the distance between the side face of the leg portion 19a and the side face of the opening 18a of the cap layer 18 becomes longer with a decreasing distance from the nitride semiconductor layer (barrier layer 14).

The space between the side face of the leg portion 19a of the gate electrode 19 and the side surface of the opening 18a of the cap layer 18 is filled with a sidewall 20 made of a first dielectric film. The first dielectric film is made of, for example, SiN or SiO₂.

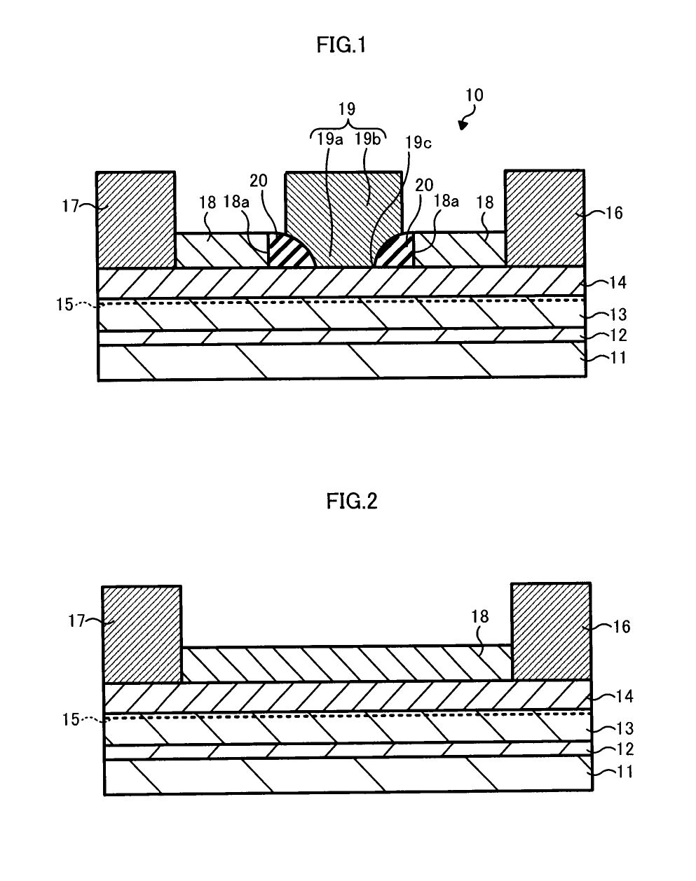

Next, the method for manufacturing the semiconductor device 10 described above will be described with reference to FIGS. 2 to 7. Each of FIGS. 2 to 7 is a sectional view corresponding to FIG. 1 to illustrate the method for manufacturing the semiconductor device 10 according to the first embodiment.

First, as shown in FIG. 2, the buffer layer 12, the channel layer 13, the barrier layer 14, and the cap layer 18 are stacked on the semi-insulating semiconductor substrate 11 in this order. Each of the layers 12, 13, 14, 18 is formed by applying, for example, the MOCVD method or the MBE method to allow epitaxial growth.

Subsequently, a portion of the cap layer 18 is removed in places where the drain electrode 16 and the source electrode 17 are formed so as to expose the barrier layer 14 therein. Then, the drain electrode 16 and the source electrode 17 are formed so as to be in ohmic contact with the barrier layer 14 exposed by the cap layer 18 being removed. The drain electrode 16 and the source electrode 17 may be provided by depositing, for example, a Ti film, Nb film, and Pt film in this order by applying the evaporation method or sputter method and removing unnecessary films by the lift-off method or the like.

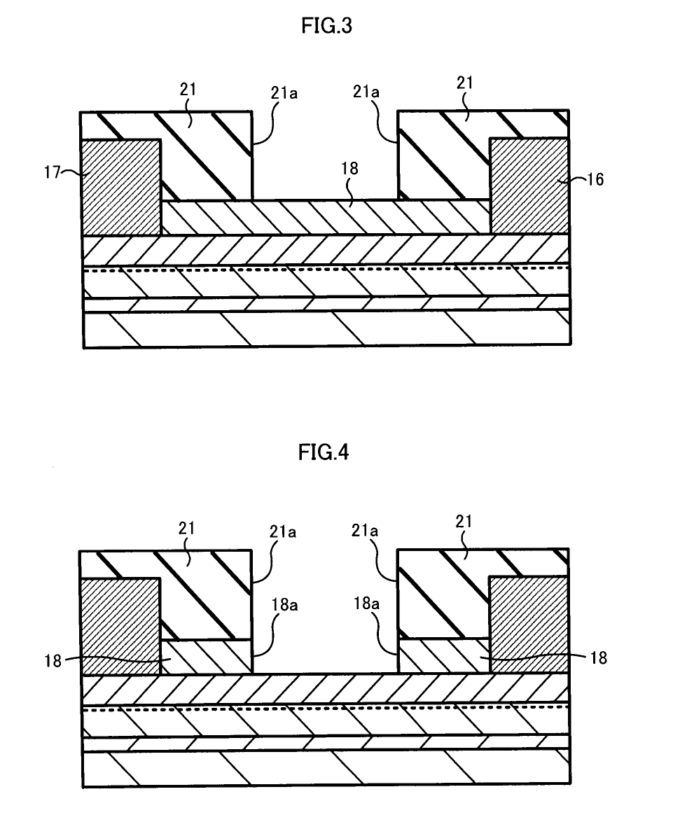

Next, as shown in FIG. 3, a resist film 21 having an opening 21a in a portion of the space between the drain electrode 16 and the source electrode 17 is formed on the cap layer 18, the drain electrode 16, and the source electrode 17.

Then, as shown in FIG. 4, the cap layer 18 exposed through the opening 21a of the resist film 21 is removed by, for example, the dry etching method to form the opening 18a in the cap layer 18.

Next, after the resist film 21 being removed, as shown in FIG. 5, a first dielectric film 20′ is formed on the cap layer 18 between the drain electrode 16 and the source electrode 17 by using the plasma CVD method or the like so that the opening 18a is filled.

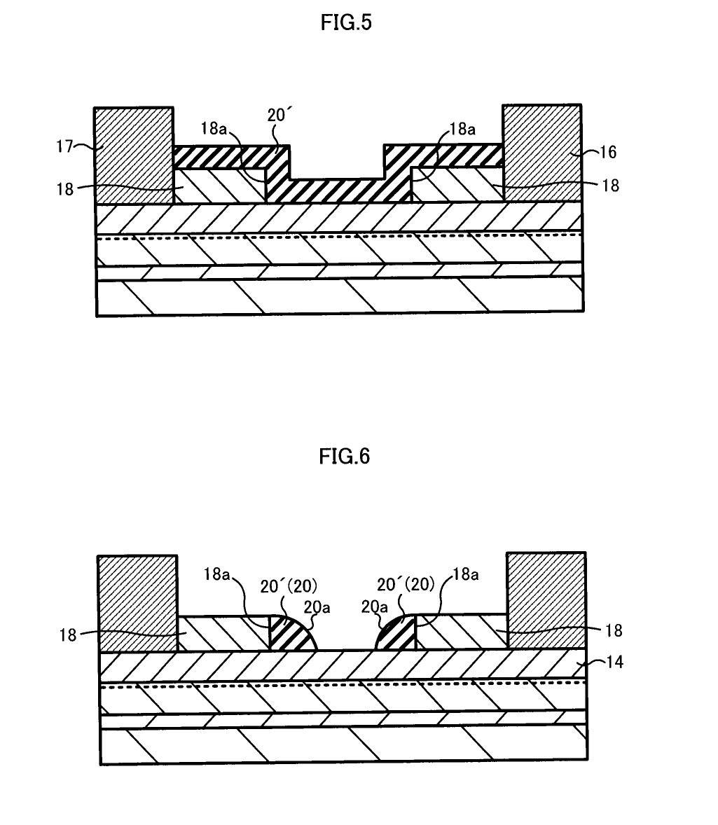

Next, anisotropic dry etching such as the RIE method is performed on the first dielectric film 20′ to remove the first dielectric film 20′ so that, as shown in FIG. 6, a portion of the first dielectric film 20′ in contact with the side surface of the opening 18a of the cap layer 18 remains. The remaining first dielectric film 20′ after the process becomes the sidewall 20. Each of the formed sidewalls 20 has an inclined plane 20a. Each of the inclined planes 20a is inclined in such a way that the distance between the inclined planes 20a becomes shorter with a decreasing distance from the barrier layer 14.

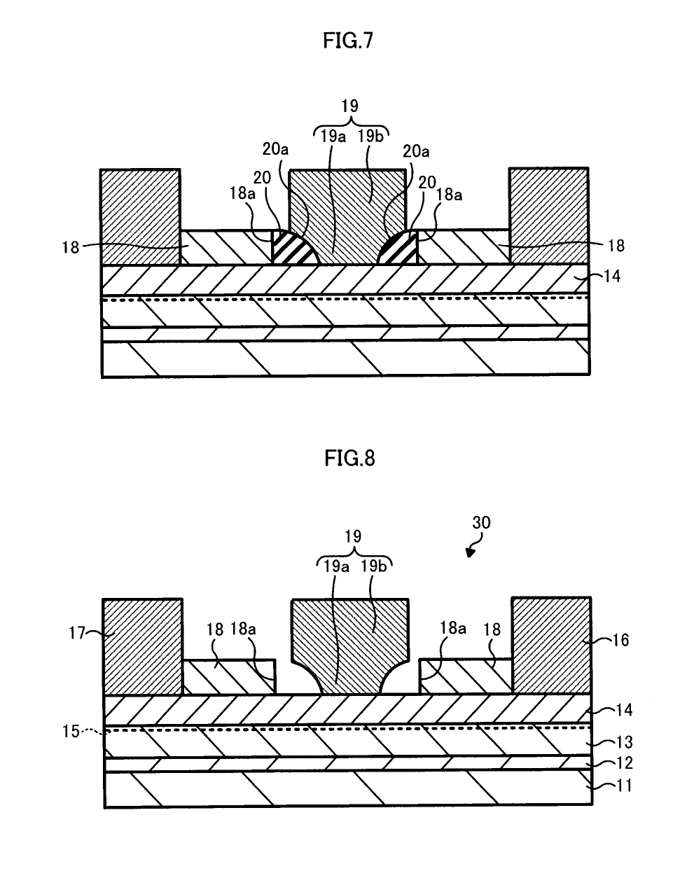

Next, as shown in FIG. 7, the gate electrode 19 is formed so as to fill the space between the sidewalls 20 and further to project upward from the opening 18a of the cap layer 18. The gate electrode 19 may be provided by stacking, for example, an Ni film and Au film in this order by applying the evaporation method or sputter method and removing unnecessary films by the lift-off method or the like.

The gate electrode 19 formed in the process has a T shape including the leg portion 19a and the eaves portion 19b projecting upward from the leg portion 19a. The leg portion 19a fills the space between the sidewalls 20 and also is Schottky-joined to the barrier layer 14 exposed between the sidewalls 20. Further, the height of the leg portion 19a is substantially equal to the thickness of the cap layer 18.

The sidewall 20 has, as described above, the inclined plane 20a inclined in such a way that the distance between the sidewalls 20 becomes shorter with a decreasing distance from the barrier layer 14 and the leg portion 19a of the gate electrode 19 is provided so as to fill the space between the sidewalls 20. Therefore, the leg portion 19a of the gate electrode 19 is insulated from the cap layer 18 by sidewall 20. And a length of the leg portion 19a becomes shorter with a decreasing distance from the barrier layer 14. Accordingly, the distance between the side face of the leg portion 19a of the gate electrode 19 and the side face of the opening 18a of the cap layer 18 becomes shorter with an increasing distance from the barrier layer 14.

Incidentally, the gate electrode 19 as described above is provided by using the sidewall 20 and so can be manufactured easily.

The semiconductor device 10 according to the first embodiment is manufactured by undergoing each process described above.

According to the semiconductor device 10 according to the first embodiment and the method for manufacturing the semiconductor device 10 according to the first embodiment, as described above, the cap layer 18 is provided on the barrier layer 14 and therefore, the current collapse can be suppressed. Further, even if the barrier layer 14 is provided thickly to suppress the current collapse more efficiently, since the gate electrode 19 is provided by being insulated from the cap layer 18, a leak current can be suppressed.

Further, a high voltage is applied to an edge portion 19c (FIG. 1) on the drain side of the gate electrode 19 and so the lower in the cap layer 18, the more leak current flows normally, but in the semiconductor device 10 according to the first embodiment, the distance between the side face of the leg portion 19a of the gate electrode 19 and the side surface of the opening 18a of the cap layer 18 becomes longer with a decreasing distance from the barrier layer 14. Thus, the higher the voltage applied and the more a leak current flows, the longer the distance between the side face of the leg portion 19a of the gate electrode 19 and the side surface of the opening 18a of the cap layer 18 and thus, a leak current can be suppressed more efficiently.

### Second Embodiment

FIG. 8 is a sectional view showing a semiconductor device according to a second embodiment. A semiconductor device according to the second embodiment will be described below with reference to FIG. 8. In the description that follows, the same reference numerals as those in the first embodiment are attached to components configured similarly to the semiconductor device 10 according to the first embodiment and the description thereof is not repeated.

A semiconductor device 30 shown in FIG. 8 is different from the semiconductor device 10 according to the first embodiment in that the sidewall is removed. That is, in the semiconductor device 30 according to the second embodiment, the gate electrode 19 is provided so as to be insulated from the cap layer 18. However, there is a space between the side face of the leg portion 19a of the gate electrode 19 and the side surface of the opening 18a of the cap layer 18. The space may be a vacuum or filled with the air.

The semiconductor device 30 is manufactured, after a semiconductor device being formed as shown in FIG. 7, by the sidewall 20 being removed from the semiconductor device by using, for example, wet etching.

Also in the semiconductor device 30 according to the second embodiment and the method for manufacturing the semiconductor device 30 according to the second embodiment described above, the cap layer 18 is provided on the barrier layer 14 and therefore, the current collapse can be suppressed. Further, the gate electrode 19 is provided so as to be insulated from the cap layer 18 and therefore, a leak current can be suppressed.

In addition, the lower in the cap layer 18 where a more leak current flows, the longer the distance between the side face of the leg portion 19a of the gate electrode 19 and the side surface of the opening 18a of the cap layer 18. Therefore, a leak current can be suppressed more efficiently.

Further, in the semiconductor device 30 according to the second embodiment and the method for manufacturing the semiconductor device 30 according to the second embodiment, there is a space between the side face of the leg portion 19a of the gate electrode 19 and the side surface of the opening 18a of the cap layer 18. The dielectric constant of the space is lower than the dielectric constant of a sidewall made of the first dielectric film such as SiN and SiO₂. Therefore, the parasitic capacitance of a gate electrode can be reduced, which results in a high-performance semiconductor device.

### Third Embodiment

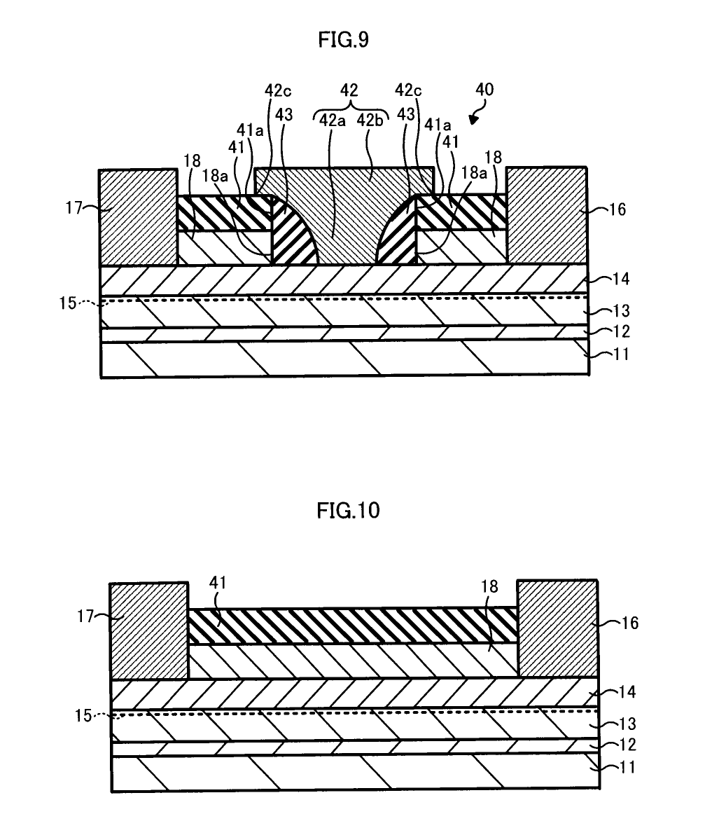

FIG. 9 is a sectional view showing a semiconductor device according to a third embodiment. A semiconductor device according to the third embodiment will be described below with reference to FIG. 9. In the description that follows, the same reference numerals as those in the first embodiment are attached to components configured similarly to the semiconductor device 10 according to the first embodiment and the description thereof is not repeated.

As shown in FIG. 9, in a semiconductor device according to the third embodiment, a second dielectric film 41 having an opening 41a communicatively connected to the opening 18a of the cap layer 18 in an upper portion thereof is provided on the surface of the cap layer 18. The second dielectric film 41 is made of, for example, SiN or SiO₂.

A gate electrode 42 is provided on the surface of the barrier layer 14 exposed through the opening 18a of the cap layer 18 and the opening 41a of the second dielectric film 41. The gate electrode 42 has, for example, an Ni layer and Au layer stacked in this order. The gate electrode 42 is provided in such a way that the Ni layer is Schottky-joined to the surface of the barrier layer 14.

The gate electrode 42 includes a leg portion 42a having an increasing length with an increasing distance from the barrier layer 14 and an eaves portion 42b having longer than the upper end of the leg portion 42a. The gate electrode 42 has a T shape in which the eaves portion 42b is provided on the leg portion 42a.

The gate electrode 42 is provided so that the whole leg portion 42a is arranged inside the opening 18a of the cap layer 18 and the opening 41a of the second dielectric film 41. Further, the gate electrode 42 is provided so that the side face of the leg portion 42a is separated from the side face of the opening 18a of the cap layer 18.

Further, the gate electrode 42 is provided so that the underside of the end of the eaves portion 42b is in contact with the surface of the second dielectric film 41.

That is, the gate electrode 42 is provided so as to be insulated from the cap layer 18. With the gate electrode 42 being provided as described above, the distance between the side face of the leg portion 42a and the side face of the opening 18a of the cap layer 18 becomes longer with a decreasing distance from the barrier layer 14.

The space between the side face of the leg portion 42a of the gate electrode 42 and the side surfaces of the opening 18a of the cap layer 18 and the opening 41a of the second dielectric film 41 is filled with a sidewall 43 made of the first dielectric film.

That is, the space between the side face of the leg portion 42a of the gate electrode 42 and the underside of the eaves portion 42b, and the cap layer 18 is filled with the dielectric films (the second dielectric film 41 and the sidewall 43).

Next, the method for manufacturing the semiconductor device 40 described above will be described with reference to FIGS. 10 to 15. Each of FIGS. 10 to 15 is a sectional view corresponding to FIG. 9 to illustrate the method for manufacturing the semiconductor device 40 according to the third embodiment.

First, as shown in FIG. 10, the buffer layer 12, the channel layer 13, the barrier layer 14, the cap layer 18, and the second dielectric film 41 are stacked on the semi-insulating semiconductor substrate 11 in this order. Each of the layers 12, 13, 14, 18 is formed by applying, for example, the MOCVD method or the MBE method to allow epitaxial growth. The second dielectric film 41 is formed by applying, for example, the plasma CVD method.

Subsequently, a portion of the second dielectric film 41 and the cap layer 18 is removed in places where the drain electrode 16 and the source electrode 17 are formed so as to expose the barrier layer 14 therein. Subsequently, the drain electrode 16 and the source electrode 17 are formed so as to be in ohmic contact with the barrier layer 14 exposed by the second dielectric film 41 and the cap layer 18 being removed.

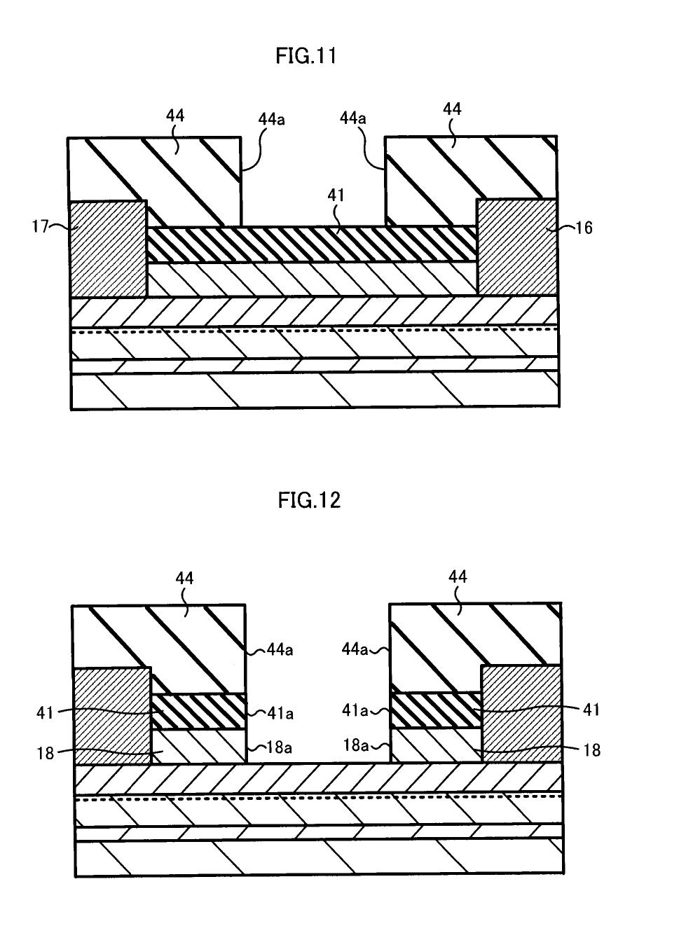

Next, as shown in FIG. 11, a resist film 44 having an opening 44a in a portion of the space between the drain electrode 16 and the source electrode 17 is formed on the second dielectric film 41, the drain electrode 16, and the source electrode 17.

Then, as shown in FIG. 12, the second dielectric film 41 exposed through the opening 44a of the resist film 44 and the cap layer 18 thereunder are removed by, for example, the dry etching method. Accordingly, the opening 41a is formed in the second dielectric film 41 and also the opening 18a is formed in the cap layer 18.

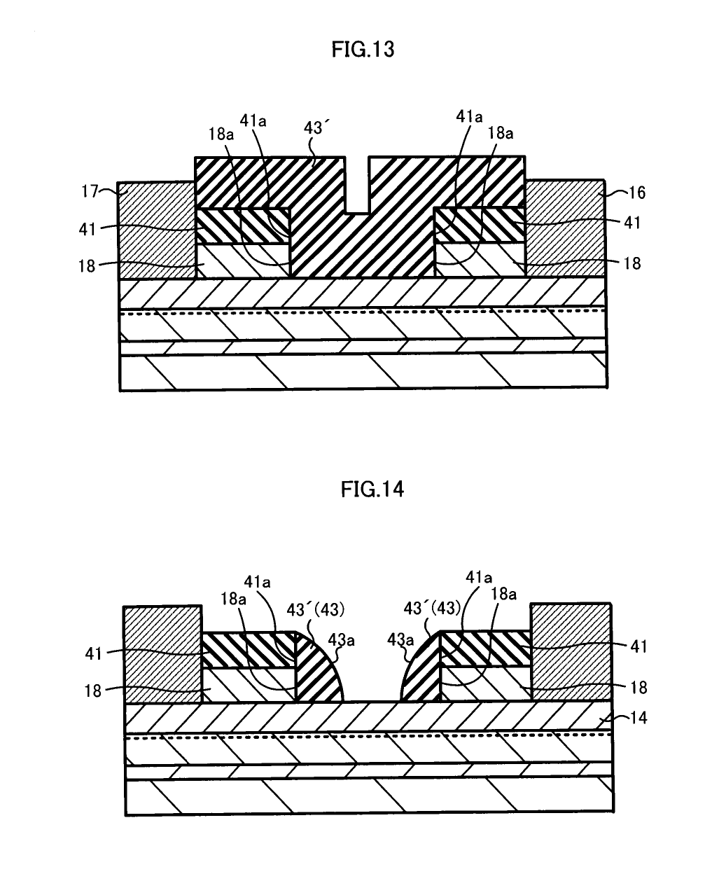

Next, after the resist film 44 being removed, as shown in FIG. 13, a first dielectric film 43′ is formed on the second dielectric film 41 between the drain electrode 16 and the source electrode 17 so that the opening 18a of the cap layer 18 and the opening 41a of the second dielectric film 41 are filled.

Next, anisotropic dry etching such as the RIE method is performed on the first dielectric film 43′ to remove the first dielectric film 43′ so that, as shown in FIG. 14, a portion of the first dielectric film 43′ in contact with the side surface of the opening 18a of the cap layer 18 and a portion of the first dielectric film 43′ in contact with the side surface of the opening 41a of the second dielectric film 41 remain. The remaining first dielectric film 43′ after the process becomes the sidewall 43. Each of the formed sidewalls 43 has an inclined plane 43a. Each of the inclined planes 43a is inclined in such a way that the distance between the inclined planes 43a becomes shorter with a decreasing distance from the barrier layer 14.

Next, as shown in FIG. 15, the gate electrode 42 is formed so as to fill the space between the sidewalls 43 and further to project upward from the opening 41a of the second dielectric film 41.

The gate electrode 42 formed in the process has a T shape including the leg portion 42a and the eaves portion 42b projecting upward from the leg portion 42a. The leg portion 42a fills the space between the sidewalls 43 and also is Schottky-joined to the barrier layer 14 exposed between the sidewalls 43. Further, the height of the leg portion 42a is higher than the thickness of the cap layer 18.

Each of the sidewalls 43 has, as described above, the inclined plane 43a inclined in such a way that the distance therebetween becomes shorter with a decreasing distance from the barrier layer 14. Then, the leg portion 42a of the gate electrode 42 is provided so as to fill the space between the sidewalls 43. Therefore, the leg portion 42a of the formed gate electrode 42 is insulated from the cap layer 18 with the sidewall 43. And a length of the leg portion 42a becomes shorter with a decreasing distance from the barrier layer 14. Accordingly, the distance between the side face of the leg portion 42a of the gate electrode 42 and the side face of the opening 18a of the cap layer 18 becomes longer with a decreasing distance from the barrier layer 14.

Further, the eaves portion 42b of the gate electrode 42 is provided so that the underside thereof is in contact with the surface of the second dielectric film 41. Therefore, the leg portion 42b of the formed gate electrode 42 is insulated from the cap layer 18 with the second dielectric film 41.

Incidentally, the gate electrode 42 as described above is provided by using the sidewall 43 and so can be manufactured easily.

The semiconductor device 40 according to the third embodiment is manufactured by undergoing each process described above.

Also in the semiconductor device 40 according to the third embodiment and the method for manufacturing the semiconductor device 40 according to the third embodiment described above, the cap layer 18 is provided on the barrier layer 14. Therefore, the current collapse can be suppressed. Further, the gate electrode 42 is provided so as to be insulated from the cap layer 18. Therefore, a leak current can be suppressed.

Further, the lower in the cap layer 18 where a more leak current flows, the longer the distance between the side face of the leg portion 42a of the gate electrode 42 and the side surface of the opening 18a of the cap layer 18. Therefore, a leak current can be suppressed more efficiently.

Also in the semiconductor device 40 according to the third embodiment and the method for manufacturing the semiconductor device 40 according to the third embodiment, as shown in FIG. 9, in addition to the drain-side end of the leg portion 42a, an edge portion 42c to which a high voltage is applied is included also at the end of the eaves portion 42b. If the portion 42c should be in contact with the cap layer 18, a leak current flows from the edge portion 42c to the cap layer 18. In the semiconductor device 40 according to the present embodiment, however, the second dielectric film 41 is provided between the underside of the eaves portion 42b and the cap layer 18. Therefore, a leak current flowing from the edge portion 42c to the cap layer 18 can be suppressed.

### Fourth Embodiment

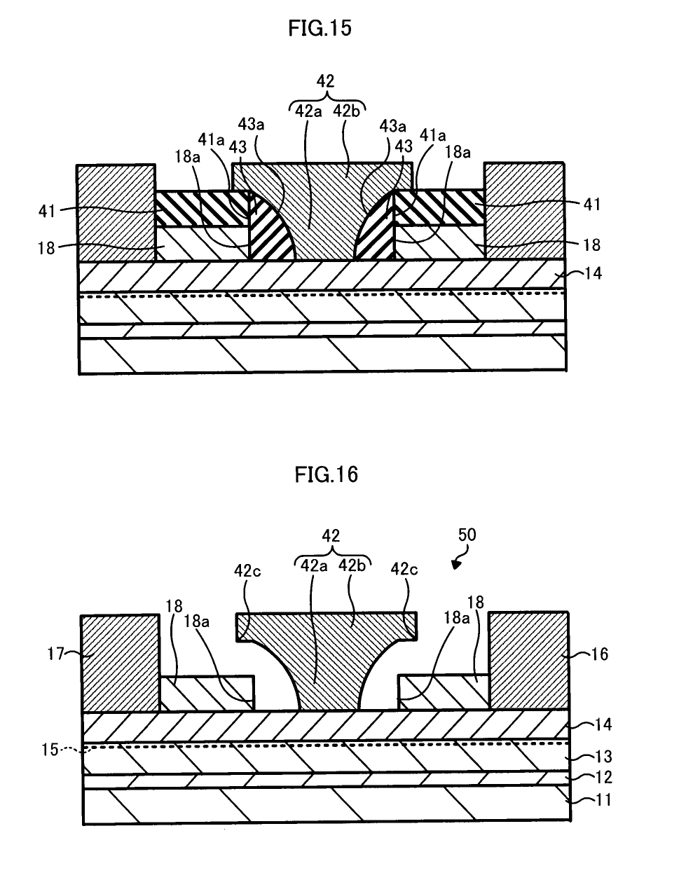

FIG. 16 is a sectional view showing a semiconductor device according to a fourth embodiment. A semiconductor device according to the fourth embodiment will be described below with reference to FIG. 16. In the description that follows, the same reference numerals as those in the third embodiment are attached to components configured similarly to the semiconductor device 40 according to the third embodiment and the description thereof is not repeated.

A semiconductor device 50 shown in FIG. 16 is different from the semiconductor device 40 according to the third embodiment in that the sidewall is removed. That is, in the semiconductor device 50 according to the fourth embodiment, the gate electrode 42 is provided so as to be insulated from the cap layer 18. However, there is a space between the side face of the leg portion 42a of the gate electrode 42 and the side surface of the opening 18a of the cap layer 18 and also between the underside of the eaves portion 42b of the gate electrode 42 and the surface of the cap layer 18. The space may be a vacuum or filled with the air.

The semiconductor device 50 is manufactured, after a semiconductor device being formed as shown in FIG. 15, by the sidewall 43 being removed from the semiconductor device by using, for example, wet etching.

Also in the semiconductor device 50 according to the fourth embodiment and the method for manufacturing the semiconductor device 50 according to the fourth embodiment described above, the cap layer 18 is provided on the barrier layer 14. Therefore, the current collapse can be suppressed. Further, the gate electrode 42 is provided so as to be insulated from the cap layer 18. Therefore, a leak current can be suppressed.

Further, the lower in the cap layer 18 where a more leak current flows, the longer the distance between the side face of the leg portion 42a of the gate electrode 42 and the side surface of the opening 18a of the cap layer 18. Therefore, a leak current can be suppressed more efficiently.

Further, the underside of the eaves portion 42b is insulated from the cap layer 18. Therefore, a leak current flowing from the edge portion 42c to the cap layer 18 can be suppressed.

In addition, in the semiconductor device 50 according to the fourth embodiment and the method for manufacturing the semiconductor device 50 according to the fourth embodiment, there is a space between the side face of the leg portion 42a of the gate electrode 42 and the side surface of the opening 18a of the cap layer 18 and also between the underside of the eaves portion 42b of the gate electrode 42 and the surface of the cap layer 18. The dielectric constant of these spaces is lower than the dielectric constant of a sidewall made of the first dielectric film such as SiN and SiO₂ and the second dielectric film. Therefore, the parasitic capacitance of a gate electrode can be reduced, which results in a high-performance semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, GaN semiconductor devices have been described in each of the above embodiments. However, the relationship between the gate electrodes 19, 42 and the cap layer 18 described above may also be applied to an Si semiconductor device or GaAs semiconductor device. That is, in an Si semiconductor device in which a semiconductor layer including a channel layer is provided on a semiconductor substrate of Si or the like, the gate electrodes 19, 42 and the cap channel 18 described above may be provided on the semiconductor layer. And, in a GaAs semiconductor device in which a compound semiconductor layer having a channel layer made of GaAs and a barrier layer made of AlGaAs is provided as a semiconductor layer on a semi-insulating semiconductor substrate, the gate electrodes 19, 42 and the cap channel 18 described above may be provided on the compound semiconductor layer.

What is claimed is:

1. A semiconductor device, comprising:
a semiconductor layer including a channel layer, a barrier layer, and a cap layer, the semiconductor layer provided on a semiconductor substrate;
a drain electrode and a source electrode provided on the barrier layer;
an opening provided in the cap layer provided between the drain electrode and the source electrode, the opening being separated from the drain electrode and the source electrode; and
a gate electrode provided so as to be in contact with the barrier layer exposed through the opening of the cap layer and insulated from a side surface of the opening of the cap layer, wherein
a distance between the gate electrode and the side surface of the opening becomes longer inside the opening with a decreasing distance from the barrier layer.

2. The semiconductor device according to claim 1, wherein a length of the gate electrode inside the opening increases with an increasing distance from the barrier layer.

3. The semiconductor device according to claim 1, wherein the gate electrode has a T shape including
a leg portion provided inside the opening and having substantially a same height as a thickness of the cap layer and
an eaves portion provided on the leg portion and having a same length as the length of an upper end of the leg portion.

4. The semiconductor device according to claim 3, wherein a dielectric film is provided between the side surface of the opening and the leg portion of the gate electrode inside the opening.

5. The semiconductor device according to claim 3, wherein there is a space between the side surface of the opening and the leg portion of the gate electrode inside the opening.

6. The semiconductor device according to claim 3, wherein the semiconductor layer is a nitride semiconductor layer.

7. The semiconductor device according to claim 6, wherein the nitride semiconductor layer includes a GaN layer to be the channel layer,
an AlGaN layer provided on the GaN layer and to be the barrier layer, and
a GaN layer provided on the AlGaN layer and to be the cap layer.

8. The semiconductor device according to claim 1, wherein the gate electrode has a T shape including
a leg portion whose portion is provided inside the opening and having a height higher than a thickness of the cap layer and
an eaves portion provided on the leg portion and having a length longer than the leg portion and
the eaves portion of the gate electrode is provided so that an underside of the eaves portion is separated upward from a surface of the cap layer.

9. The semiconductor device according to claim 8, wherein a dielectric film is provided between the side surface of the opening and the surface of the cap layer, and the gate electrode.

10. The semiconductor device according to claim 8, wherein there is a space between the side surface of the opening and the surface of the cap layer, and the gate electrode.

11. The semiconductor device according to claim 8, wherein the semiconductor layer is a nitride semiconductor layer.

12. The semiconductor device according to claim 11, wherein the nitride semiconductor layer includes a GaN layer to be the channel layer,
an AlGaN layer provided on the GaN layer and to be the barrier layer, and
a GaN layer provided on the AlGaN layer and to be the cap layer.

13. A method for manufacturing a semiconductor device, comprising:
forming a channel layer, a barrier layer, and a cap layer on a semiconductor substrate;
forming a drain electrode and a source electrode on the barrier layer;
forming an opening in the cap layer formed between the drain electrode and the source electrode, the opening being separated from the drain electrode and the source electrode;
forming a first dielectric film on the cap layer including the opening;
forming a sidewall inside the opening by performing anisotropic etching on the first dielectric film; and
forming a gate electrode so that at least the opening in which the sidewall is provided is filled.

14. The method according to claim 13,
wherein after the gate electrode being formed, the sidewall is further removed.

15. The method according to claim 13,
wherein the channel layer, the barrier layer, and the cap layer are each nitride semiconductor layers.

16. The method according to claim 15,
wherein the channel layer is a GaN layer,
the barrier layer is an AlGaN layer, and
the cap layer is a GaN layer.

17. A method for manufacturing a semiconductor device, comprising:
forming a channel layer, a barrier layer, a cap layer, and a second dielectric film on a semiconductor substrate;
forming a drain electrode and a source electrode on the barrier layer;
forming an opening in the cap layer and the second dielectric film formed between the drain electrode and the source electrode, the opening being separated from the drain electrode and the source electrode;
forming a first dielectric film on the second dielectric film including the opening;
forming a sidewall inside the opening by performing anisotropic etching on the first dielectric film; and
forming a gate electrode so that at least the opening in which the sidewall is provided is filled.

18. The method according to claim 17,
wherein after the gate electrode being formed, the sidewall and the second dielectric film are further removed.

19. The method according to claim 17,
wherein the channel layer, the barrier layer, and the cap layer are each nitride semiconductor layers.

20. The method according to claim 19,
wherein the channel layer is a GaN layer,
the barrier layer is an AlGaN layer, and
the cap layer is a GaN layer.
